(19) United States
(12) Patent Application Publication
(10) Pub. No.: US 2025/0147122 A1
(43) Pub. Date: May 8, 2025

(54) ELECTRIC LEAKAGE DETECTION DEVICE AND METHOD, AND VEHICLE

(71) Applicant: BYD COMPANY LIMITED, SHENZHEN (CN)

(72) Inventors: Mingwen CHEN, Shenzhen (CN); Penghui XUE, Shenzhen (CN); Xiangxiang LI, Shenzhen (CN); Lei SHI, Shenzhen (CN); Weicheng LI, Shenzhen (CN)

(21) Appl. No.: 19/017,061

(22) Filed: Jan. 10, 2025

Related U.S. Application Data
(63) Continuation of application No. PCT/CN2023/104817, filed on Jun. 30, 2023.

(30) Foreign Application Priority Data
Jul. 28, 2022 (CN) 202210898895.X

(51) Int. Cl. G01R 31/52; G01R 19/165; G01R 31/00

(52) U.S. Cl. CPC G01R 31/52; G01R 19/16576; G01R 31/006

(57) ABSTRACT

A device for detecting electric leakage, includes: a detection assembly connected to a first phase discharge path, a second phase discharge path, and a sampling assembly which is connected to a signal processing circuit. The first and the second phase discharge paths are configured to connect to a power supply and transmit electricity from the power supply when the power supply discharges electricity. The detection assembly is configured to establish the detection loop when the power supply discharges electricity. The sampling assembly is configured to collect, from the detection loop, a first detected voltage of the first phase discharge path and a second detected voltage of the second phase discharge path. The signal processing circuit is configured to receive the first and the second detected voltages from the sampling assembly, and determine whether the power supply has electric leakage according to the first and the second detected voltages.

### CROSS-REFERENCE TO RELATED APPLICATIONS

This application is a continuation application of International Patent Application No. PCT/CN2023/104817, filed on Jun. 30, 2023, which is based on and claims priority to and benefits of Chinese Patent Application No. 202210898895.X, filed on Jul. 28, 2022. The entire content of all of the above-referenced applications is incorporated herein by reference.

### FIELD

The present disclosure relates to the field of driving devices, and particularly, to an electric device for detecting electric leakage, a method and a vehicle.

### BACKGROUND

As the new energy electric vehicle progresses, the demand for the new energy electric vehicles are increased, and there is a growing need for vehicles to have discharge functions. When a vehicle power supply supplies power to an external electric device, the electric-leakage detection and protection of the power supply is currently a major challenge.

At present, in the electric-leakage detection of the electric vehicle, the positive and negative direct current (DC) power supplies are applied between the high-voltage loop and the vehicle body, to configure a loop with the insulation resistance of the whole vehicle, and to obtain the change in the insulation resistance value of the whole vehicle. Since the device for detecting electric leakage is provided between the high-voltage loop and the vehicle body, it is necessary to increase the current flowing through the high-voltage loop during the operation of the device for detecting electric leakage, and the insulation performance of the whole vehicle is affected.

### SUMMARY

In view of the above technical problems, embodiments of the present disclosure propose an electric device and a detection method for detecting electric leakage, and a vehicle that executes a fault detection by the electric device for detecting electric leakage, which can improve the reliability of electric-leakage detection of a power supply discharge loop and improve the insulation characteristics of the an alternating current (AC) output end of the power supply.

An embodiment of the present disclosure discloses a device for detecting electric leakage includes a detection assembly, a sampling assembly, and a signal processing circuit. The detection assembly is connected to a first phase discharge path and a second phase discharge path, the first phase discharge path and the second phase discharge path are configured to connect a power supply and transmit electricity outputted from the power supply when the power supply discharges electricity, and the detection assembly is configured to establish a detection loop for the first phase discharge path and the second phase discharge path when the power supply discharges electricity. The sampling assembly is connected to the detection assembly and is configured to collect, from the detection loop, a first detected voltage of the first phase discharge path and a second detected voltage of the second phase discharge path. The signal processing circuit is connected to the sampling assembly, and is configured to receive the first detected voltage and the second detected voltage from the sampling assembly, and determine whether the power supply has electric leakage according to the first detected voltage and the second detected voltage.

In an embodiment, the detection assembly includes a first detection circuit and a second detection circuit, wherein the first detection circuit is connected between the first phase discharge path and a low-voltage ground, and the second detection circuit is connected between the second phase discharge path and the low-voltage ground. The sampling assembly is used to collect the first detected voltage from the first detection circuit and collect the second detected voltage from the second detection circuit.

In an embodiment, the first detection circuit includes a first detection voltage-stabilization circuit, a first unidirectional conduction circuit, and a sampling circuit, the first detection voltage-stabilization circuit, the first unidirectional conduction circuit, and the sampling circuit are sequentially connected in series between the first phase discharge path and the low-voltage ground. The second detection circuit includes a second detection voltage-stabilization circuit and a second unidirectional conduction circuit, the second detection voltage-stabilization circuit, the second unidirectional conduction circuit, and the sampling circuit are sequentially connected in series between the second phase discharge path and the low-voltage ground.

In an embodiment, the first detection voltage-stabilization circuit includes a first switch, the first unidirectional conduction circuit includes a first diode, and the sampling circuit includes a first resistor, a sampling node, and a sampling resistor. The first switch, the first diode, the first resistor, and the sampling resistor are connected in series between the first phase discharge path and the low-voltage ground, an anode of the first diode is connected to the first switch, a cathode of the first diode is connected to the first resistor, and the sampling node is a node between the first resistor and the sampling resistor. The second detection voltage-stabilization circuit includes a second switch, the second unidirectional conduction circuit includes a second diode, the second switch, the second diode, the first resistor, and the sampling resistor are connected in series between the second phase discharge path and the low-voltage ground, an anode of the second diode is connected to the second switch, and a cathode of the second diode is connected to the first resistor. The sampling assembly collects the first detected voltage and the second detected voltage from the sampling node.

In an embodiment, the first detection voltage-stabilization circuit includes a first detection voltage-stabilization capacitor, the first unidirectional conduction circuit includes a first diode, and the sampling circuit includes a first resistor, a sampling node, and a sampling resistor. The first detection voltage-stabilization capacitor, the first diode, the first resistor, and the sampling resistor are connected in series between the first phase discharge path and the low-voltage ground. An anode of the first diode is connected to the first detection voltage-stabilization capacitor, a cathode of the first diode is connected to the first resistor, and the sampling node is a node between the first resistor and the sampling resistor. The second detection voltage-stabilization circuit includes a second detection voltage-stabilization capacitor, the second unidirectional conduction circuit includes a second diode, the second detection voltage-stabilization capacitor, the second diode, the first resistor, and the sampling resistor are connected in series between the second phase discharge path and the low-voltage ground, an anode of the second diode is connected to the second detection voltage-stabilization capacitor, and a cathode of the second diode is connected to the first resistor. The sampling assembly collects the first detected voltage and the second detected voltage from the sampling node.

In an embodiment, the sampling assembly includes a differential operational amplifier, a second resistor, a third resistor, and a third capacitor, a positive-phase end of the differential operational amplifier is connected to the sampling node and is used to collect the first detected voltage and the second detected voltage from the sampling node. The second resistor and the third capacitor are connected in series between a reverse-phase end of the differential operational amplifier and a device ground, and the reverse-phase end of the differential operational amplifier is connected to an output end of the differential operational amplifier through the third resistor, and are used to increase or decrease the first detected voltage and the second detected voltage according to a proportion and output the first detected voltage and the second detected voltage from the output end of the differential operational amplifier.

In an embodiment, the detection assembly is further connected to a third phase discharge path, and the power supply is a three-phase alternating current power supply and outputs, respectively through the first phase discharge path, the second phase discharge path, and the third phase discharge path, currents with a same amplitude, a same frequency, and a same phase difference.

In an embodiment, the detection assembly includes a first detection circuit and a second detection circuit, and the first detection circuit is connected between the first phase discharge path and a device ground and is connected to the second phase discharge path by the device ground. The second detection circuit is connected between the second phase discharge path and the device ground, and is connected to the first phase discharge path through the device ground.

In an embodiment, the first detection circuit includes a first detection voltage-stabilization circuit, a first path voltage-stabilization circuit, a first voltage division circuit, and a sampling circuit. The first detection voltage-stabilization circuit, the first voltage division circuit, and the sampling circuit are connected in series between the first phase discharge path and the device ground, and the first path voltage-stabilization circuit is connected between the second phase discharge path and the device ground. The second detection circuit includes a second detection voltage-stabilization circuit, a second path voltage-stabilization circuit, and a second voltage division circuit. The second detection voltage-stabilization circuit, the second voltage division circuit, and the sampling circuit are connected in series between the second phase discharge path and the device ground, and the second path voltage-stabilization circuit is connected between the first phase discharge path and the device ground.

In an embodiment, the first detection voltage-stabilization circuit includes a first switch, the first voltage division circuit includes a first diode and a first resistor, the sampling circuit includes a sampling resistor and a sampling node, and the first path voltage-stabilization circuit includes a first path voltage-stabilization capacitor, the first switch, the first diode, the first resistor and the sampling resistor are connected in series between the first phase discharge path and the device ground, an anode of the first diode is connected to the first switch, a cathode of the first diode is connected to the first resistor, the sampling node is a node between the first resistor and the sampling resistor, and the first path voltage-stabilization capacitor is connected between the device ground and the second phase discharge path. The second detection voltage-stabilization circuit includes a second switch, the second voltage division circuit includes a second diode and a second resistor, and the second path voltage-stabilization circuit comprises a second path voltage-stabilization capacitor, the second switch, the second diode, the second resistor and the sampling resistor are connected in series between the second phase discharge path and the device ground, an anode of the second diode is connected to the second switch, a cathode of the second diode is connected to the second resistor, and the second path voltage-stabilization capacitor is connected between the device ground and the first phase discharge path. The sampling assembly is used to collect the first detected voltage and the second detected voltage from the sampling node.

In an embodiment, the first detection voltage-stabilization circuit includes a first detection voltage-stabilization capacitor, the first path voltage-stabilization circuit includes a first path voltage-stabilization capacitor, the first voltage division circuit includes a first diode and a first resistor, and the sampling circuit includes a sampling node and a sampling resistor. The first detection voltage-stabilization capacitor, the first diode, the first resistor and the sampling resistor are connected in series between the first phase discharge path and the device ground, an anode of the first diode is connected to the first detection voltage-stabilization capacitor, a cathode of the first diode is connected to the first resistor, the sampling node is a node between the first resistor and the sampling resistor, and the first path voltage-stabilization capacitor is connected between the device ground and the second phase discharge path. The second detection voltage-stabilization circuit includes a second detection voltage-stabilization capacitor, the second voltage division circuit includes a second diode and a second resistor, and the second path voltage-stabilization circuit includes a second path voltage-stabilization capacitor; the second detection voltage-stabilization capacitor, the second diode, the second resistor and the sampling resistor are connected in series between the second phase discharge path and the device ground, an anode of the second diode is connected to the second detection voltage-stabilization capacitor, a cathode of the second diode is connected to the second resistor, and the second path voltage-stabilization capacitor is connected between the device ground and the first phase discharge path. The sampling assembly is used to collect the first detected voltage and the second detected voltage from the sampling node.

In an embodiment, the sampling assembly includes a voltage follower, a positive-phase end of the voltage follower is connected to the sampling node, and is used to collect the first detected voltage and the second detected voltage from the sampling node, and a reverse-phase end of the voltage follower is connected to an output end of the voltage follower, and is configured to increase or decrease the collected first detected voltage and the second detected voltage according to a proportion, and to output the collected first detected voltage and the second detected voltage from the output end of the voltage follower.

In an embodiment, the signal processing circuit includes a clamping circuit and a digital signal processor, the clamping circuit is connected to the sampling assembly and the digital signal processor, and the clamping circuit is configured to clamp the first detected voltage and the second detected voltage received from the sampling assembly to a voltage range and to output the first detected voltage and the second detected voltage to the digital signal processor. The digital signal processor is configured to receive the first detected voltage and the second detected voltage, and to determine whether the power supply has electric leakage according to the first detected voltage and the second detected voltage.

An embodiment of the present disclosure further discloses a method for detecting electric leakage, applied to the aforementioned device for detecting electric leakage or electric vehicle. The method includes: when the power supply discharges electricity through the first phase discharge path, the first detection circuit is conducted to control the sampling assembly such that the first detected voltage is collected from the first detection circuit. When the power supply discharges electricity through the second phase discharge path, the second detection circuit is conducted to control the sampling assembly to collect a second detected voltage from the second detection circuit. The voltage difference between the first detected voltage and the second detected voltage is compared with a threshold voltage, and determine that the power supply has electric leakage when the voltage difference is greater than the threshold voltage.

An embodiment of the present disclosure also discloses a vehicle, includes the aforementioned device for detecting electric leakage, the power supply is configured to be connected to a first phase discharge path and a second phase discharge path, and the power supply discharges electricity through the first phase discharge path and the second phase discharge path and outputs an alternating current, and the device for detecting electric leakage is configured to detect electric leakage on the first phase discharge path and the second phase discharge path when the power supply discharges electricity.

In comparison with the prior art, the device for detecting electric leakage provided by the present disclosure establishes an electric-leakage detection loop for the first phase discharge path and the second phase discharge path of the power supply, respectively, so as to directly and quickly perform electric-leakage detection on the power supply discharge loop during power supply discharges, effectively avoids the defect of large impedance of the detection loop caused by directly arrange/configure the device for detecting electric leakage between the high voltage loops of the power supply, thereby effectively improving the reliability of electric-leakage detection of the power discharge loop, and greatly improving the insulation characteristic of the power supply AC output end. When there is no leakage fault in the power supply discharge loop, the device for detecting electric leakage is in a low power consumption state, thereby reducing the consumption of electric energy. The device for detecting electric leakage has low overall power consumption and a simple structure, thereby greatly reducing the use cost and production cost of the circuit.

### BRIEF DESCRIPTION OF THE DRAWINGS

In order to more clearly illustrate the technical solutions in the embodiments of this disclosure, the accompanying drawings used in the embodiments are briefly described below. The accompanying drawings in the following description are for some embodiments of this disclosure. For a person of ordinary skill in the art, other drawings may be obtained according to these accompanying drawings without creative efforts.

FIG. 1 is a schematic block diagram of a driving device according to a first embodiment of the present disclosure;

FIG. 2 is a circuit block diagram of the device for detecting electric leakage as shown in FIG. 1 according to a second embodiment of the present disclosure;

FIG. 3 is a schematic diagram of a module connection of the device for detecting electric leakage in FIG. 2;

FIG. 4 is an equivalent circuit diagram of the device for detecting electric leakage in FIG. 3;

FIG. 5 is an equivalent circuit diagram of the device for detecting electric leakage in FIG. 3 according to a third embodiment of the present disclosure;

FIG. 6 is a schematic diagram of connections between functional modules of the device for detecting electric leakage in FIG. 2 according to a fourth embodiment of the present disclosure;

FIG. 7 is an equivalent circuit diagram of the device for detecting electric leakage in FIG. 6;

FIG. 8 is an equivalent circuit diagram of the device for detecting electric leakage in FIG. 6 according to a fifth embodiment of the present disclosure; and

FIG. 9 is a flowchart of a method for detecting electric leakage according to a sixth embodiment of the present disclosure.

### DETAILED DESCRIPTION

To facilitate understanding of the present disclosure, the present disclosure will be described more fully hereinafter with reference to the accompanying drawings. Some embodiments of the present disclosure are shown in the accompanying drawings. However, the present disclosure may be implemented in many different forms and is not limited to the embodiments described herein. Rather, the purpose of providing these embodiments is to make the disclosure of the present disclosure more thorough and comprehensive.

The following description of the embodiments is provided with reference to the accompanying drawings to illustrate embodiments that can be implemented by the present disclosure. The serial numbers of the components themselves, such as “first”, “second”, etc., are only used to distinguish the described objects, and do not have any order or technical meaning. However, the terms “connect” and “couple” in this disclosure are not specifically described, and all include direct and indirect connections (coupling). Directional terms mentioned in the present disclosure, for example, “upper”, “lower”, “front”, “rear”, “left”, “right”, “inner”, “outer”, “side”, etc., are merely directions referring to the accompanying drawings, and therefore, the directional terms used is for better, clearer description and understanding of the present disclosure, rather than indicating or implying that the apparatus or element referred to by the present disclosure must have an orientation, or be constructed and operated in an orientation, and therefore cannot be understood as a limitation to the present disclosure.

In the description of this disclosure, it should be noted that, unless otherwise clearly stated and limited, the terms “installation”, “connection” and “coupling” should be understood in a broad sense. For example, the terms can be a fixed connection, a detachable connection, or integral connection; a mechanical connection; a direct connection, an indirect connection through an intermediate medium; or an internal connection between two components. For those of ordinary skill in the art, the meanings of the above terms in this disclosure can be understood on a case-by-case basis. It should be noted that the terms “first”, “second”, etc. in the description, claims, and drawings of this disclosure are used to distinguish different objects, rather than describing a sequence.

In addition, the terms “include”, “can include”, “comprise”, or “can comprise” used in this disclosure indicate the existence of the corresponding disclosed functions, operations, elements, etc., and do not limit other one or more functions, operations, components, etc. Furthermore, the term “include” or “comprise” indicates the presence of the corresponding features, numbers, steps, operations, elements, components, or combinations thereof disclosed in the specification, but does not exclude the presence or addition of one or more other features, numbers, steps, operations, elements, parts, or combinations thereof, are to cover non-exclusive inclusion. In addition, when describing embodiments of the present disclosure, the use of “can” means “one or more embodiments of the present disclosure.” Also, the term “exemplary” is to refer to an example or illustration.

Unless otherwise defined, all technical and scientific terms used herein have the same meaning as commonly understood by one of ordinary skill in the art to which this disclosure belongs. The terms used in the description of the present disclosure are merely for the purpose of describing implementations, and are not to limit the present disclosure.

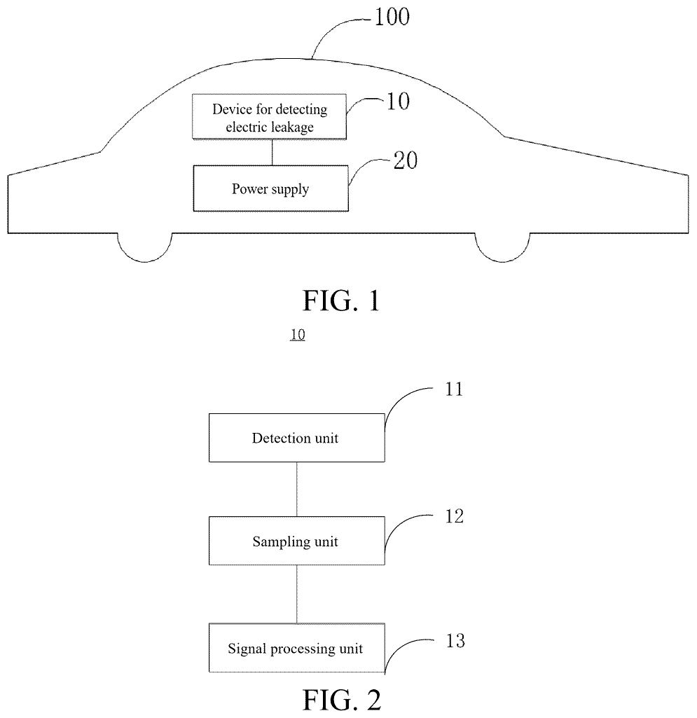

Referring to FIG. 1, FIG. 1 is a schematic block diagram of a driving device according to a first embodiment of the present disclosure. As shown in FIG. 1, the driving device 100 is a vehicle that can output electric energy to outside the vehicle body, and includes a device 10 for detecting electric leakage and a power supply 20. The device 10 for detecting electric leakage is used to perform electric-leakage detection on the high voltage loop when the vehicle outputs electric energy to the outside.

Referring to FIG. 2, FIG. 2 is a circuit block diagram of a device for detecting electric leakage as shown in FIG. 1 according to a second embodiment of the present disclosure. As shown in FIG. 2, the device for detecting electric leakage 10 includes a detection assembly 11, a sampling assembly 12, and a signal processing circuit 13.

The detection assembly 11 is separately connected to the first phase discharge path L and the second phase discharge path N, the first phase discharge path L and the second phase discharge path N are connected to a power supply 20 and transmit electricity outputted from the power supply 20 when the power supply 20 discharges electricity, and the detection assembly 11 is configured to establish a detection loop for the first phase discharge path L and the second phase discharge path N when the power supply 20 discharges electricity.

The sampling assembly 12 is electrically connected to the detection assembly 11, and is configured to separately collect, from the detection loop, a first detected voltage U_{LE} of the first phase discharge path L and/or a second detected voltage U_{NE} of the second phase discharge path N.

The signal processing circuit 13 is connected to the sampling assembly 12, and is used to asynchronously receive the first detected voltage U_{LE} and the second detected voltage U_{NE} from the sampling assembly 12, and determine the electric-leakage characteristics of the power supply (e.g., whether the power supply has electric leakage), and indicates that a electric-leakage fault occurs in the power supply 20 when the difference between the first detected voltage U_{LE} and the second detected voltage U_{NE} is greater than the threshold voltage.

In an embodiment, the power supply 20 can also be a three-phase alternating current power supply, that is, the power supply 20 is a power supply includes three alternating current potentials with the same frequency, the same amplitude, and a phase difference of 120° sequentially. Correspondingly, the power supply 20 output three currents with the same frequency, the same amplitude, and the same phase difference of 120° through a first phase discharge path, a second phase discharge path, and a third phase discharge path respectively. When the power supply 20 outputs currents through the three-phase discharge paths, the detection assembly 11 is also connected to the first phase discharge path, the second phase discharge path, and the third phase discharge path, and performs corresponding detection.

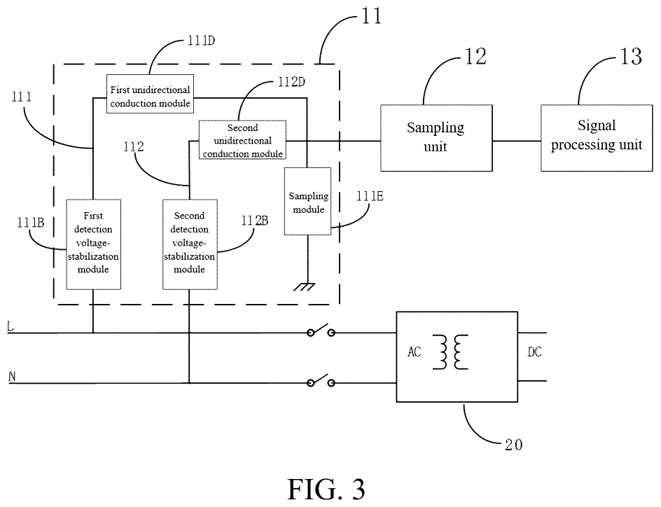

Referring to FIG. 3, FIG. 3 is a schematic diagram of a module connection of the device for detecting electric leakage in FIG. 2. As shown in FIG. 3, the detection assembly 11 includes a first detection circuit 111 and a second detection circuit 112.

The first detection circuit 111 is connected between the first phase discharge path L and the low-voltage ground GND to form a detection loop for detecting the first detected voltage U_{LE} of the first phase discharge path L, and the second detection circuit 112 is connected between the second phase discharge path N and the low voltage ground GND to form a detection loop for detecting the second detected voltage U_{NE} of the second phase discharge path N.

When the power supply 20 outputs the alternating current and the first phase discharge path L discharges electricity, the first detection circuit 111 is conducted and the sampling assembly 12 detects the first detected voltage U_{LE} from the first detection circuit 111. When the power supply 20 outputs the alternating current and the second phase discharge path N discharges electricity, the second detection circuit 112 is conducted, and the sampling assembly 12 detects the second detected voltage U_{NE} from the second detection circuit 112.

The first detection circuit 111 includes a first detection voltage-stabilization circuit 111B, a sampling circuit 111E, and a first unidirectional conduction circuit 111D. The first detection voltage-stabilization circuit 111B, the first unidirectional conduction circuit 111D, and the sampling circuit 111E are sequentially connected in series between the first phase discharge path L and the low-voltage ground GND to form the detection loop

The second detection circuit 112 includes a second detection voltage-stabilization circuit 112B and a second unidirectional conduction circuit 112D. The second detection voltage-stabilization circuit 112B, the second unidirectional conduction circuit 112D, and the sampling circuit 111E are sequentially connected in series between the second phase discharge path N and the low-voltage ground GND to form the detection loop.

The sampling assembly 12 is electrically connected to the detection assembly 11, and the detection assembly 11 is used to collect, from the detection loop, a first detected voltage U_{LE} of the first phase discharge path L and/or a second detected voltage U_{NE} of the second phase discharge path N.

The signal processing circuit 13 is connected to the sampling assembly 12, and is used to asynchronously receive the first detected voltage and the second detected voltage from the sampling assembly 12, and determine the electric-leakage characteristics of the power supply and indicates that a electric-leakage fault occurs in the power supply 20 when the difference between the first detected voltage U_{LE} and the second detected voltage U_{NE} is greater than the threshold voltage.

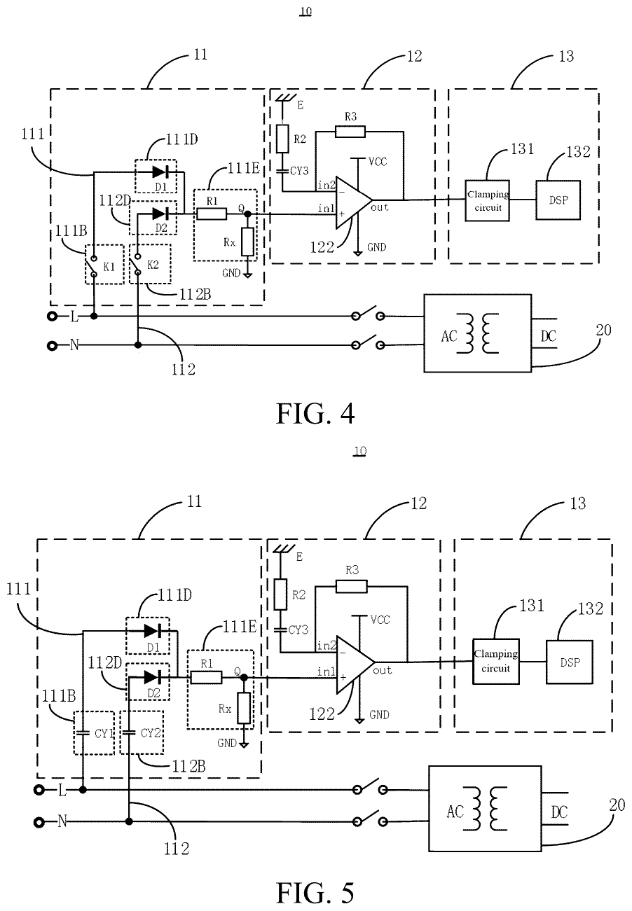

Referring to FIG. 4, FIG. 4 is an equivalent circuit diagram of the device for detecting electric leakage in FIG. 3. As shown in FIG. 4, the first detection voltage-stabilization circuit 111B includes a first switch K1, the first unidirectional conduction circuit 111D includes a first diode D1, and the sampling circuit 111E includes a first resistor R1, a sampling node Q, and a sampling resistor Rx. The first switch K1, the first diode D1, the first resistor R1 and the sampling resistor Rx are sequentially connected in series between the first phase discharge path L and the low-voltage ground GND to form the detection loop, an anode of the first diode D1 is connected to the first switch K1, the cathode of the first diode D1 is connected to the first resistor R1, and the sampling node Q is disposed between the first resistor R1 and the sampling resistor Rx to collect the first detected voltage U_{LE} by the sampling assembly 12.

The second detection voltage-stabilization circuit 112B includes a second switch K2, the second unidirectional conduction circuit 112D includes a second diode D2, the second switch K2 and the second diode D2, the first resistor R1 and the sampling resistor Rx are sequentially connected in series between the second phase discharge path N and the low-voltage ground GND to form the detection loop, and an anode of the second diode D2 is connected to the second switch K2, and a cathode of the second diode D2 is connected to the first resistor R1, the sampling assembly 12 collects the second detected voltage U_{NE} of the second phase discharge path N from the sampling node Q.

The sampling assembly 12 includes a differential operational amplifier 122, a third capacitor CY3, a second resistor R2 and a third resistor R3. The third resistor R3 is connected between the reverse-phase end in2 of the differential operational amplifier 122 and the output end, out, of the differential operational amplifier 122. The second resistor R2 and the third capacitor CY3 is connected in series to the device ground E and a reverse-phase end in2 of the differential operational amplifier 122. A positive-phase end in1 of the differential operational amplifier 122 is connected to the sampling node Q, the differential operational amplifier 122 respectively collects the first detected voltage U_{LE} and the second detected voltage U_{NE} through the sampling node Q.

When the voltage of the first phase discharge path L is greater than the voltage of the second phase discharge path N, the differential operational amplifier 122 detects the first detected voltage U_{LE} of the first phase discharge path L through the first detection circuit 111. When the voltage of the second phase discharge path N is greater than the voltage of the first phase discharge path L, the differential operational amplifier 122 detects the second detected voltage U_{NE} of the second phase discharge path N through the second detection circuit 112.

When the voltage of the first phase discharge path L is greater than the voltage of the second phase discharge path N, the positive-phase end in1 of the differential operational amplifier 122 is connected to the sampling node Q and is connected to the first phase discharge path L by the first detection circuit 111, the first detected voltage U_{LE} is collected from the sampling node Q, and the reverse-phase end in2 is connected to the device ground E through a third detection circuit, where the third detection circuit includes a second resistor R2 and a third capacitor CY3. When the circuit operates, the positive output passes through the first switch K1, the first diode D1, and the first resistor R1 to the positive-phase end in1 of the differential operational amplifier 122, and the negative input passes through the device ground E, the second resistor R2, the third capacitor CY3 to the reverse-phase end in2, and then the first detected voltage U_{LE} is output from the output end out of the differential operational amplifier 122.

When the voltage of the second phase discharge path N is greater than the voltage of the first phase discharge path L, the positive-phase end in1 of the differential operational amplifier 122 is connected to the sampling node Q and is connected to the second phase discharge path N by the second detection circuit 112, the second detected voltage U_{NE} is collected from the sampling node Q, and the reverse-phase end in2 is connected to the device ground E through the third detection circuit. When the circuit operates, the positive output passes through the second switch K2, the second diode D2, and the first resistor R1 to the positive-phase end in1 of the differential operational amplifier 122, and the negative input passes through the device ground E, the second resistor R2 and the third capacitor CY3 to the reverse-phase end in2, and then the second detected voltage U_{NE} is output from the output end out of the differential operational amplifier 122.

The differential operational amplifier 122 transmits the collected first detected voltage U_{LE} and the second detected voltage U_{NE} to the signal processing circuit 13 through the output end, out.

The signal processing circuit 13 includes a clamping circuit 131 and a digital signal processor (DSP) 132. The clamping circuit 131 is connected to the output end out of the differential operational amplifier 122 and the digital signal processor 132, and is used to adjust the received voltage values of the first detected voltage U_{LE} and the second detected voltage U_{NE} in a preset range. The digital signal processor 132 is used to compare the first detected voltage U_{LE} and the second detected voltage U_{NE} in digital form. When the difference between the first detected voltage U_{LE} and the second detected voltage U_{NE} is greater than the preset threshold, it indicates that an electric-leakage fault occurs in the power supply 20.

The device for detecting electric leakage disclosed in this embodiment can meet the requirements of the national standard “GB 18384.2020 Electric Vehicles Safety Requirements” that the alternating current discharge path, that is, the insulation resistance between the first phase discharge path L and the second phase discharge path N, is ≥ about 10 MΩ.

Referring to FIG. 5, FIG. 5 is an equivalent circuit diagram of the device for detecting electric leakage in FIG. 3, provided by the third embodiment of the present disclosure. As shown in FIG. 5, the first detection voltage-stabilization circuit 111B includes a first detection voltage-stabilization capacitor CY1, the first unidirectional conduction circuit 111D includes a first diode D1, and the sampling circuit 111E includes a first resistor R1, a sampling node Q, and a sampling resistor Rx. The first detection stabilizing capacitor CY1, the first diode D1, the first resistor R1 and the sampling resistor Rx are sequentially connected in series to the first phase discharge path L and the low-voltage ground terminal GND to form the detection loop. An anode of the first diode D1 is connected to the first detection voltage-stabilization capacitor CY1, a cathode of the first diode D1 is connected to the first resistor R1, and the sampling node Q is a node between the first resistor R1 and the sampling resistor Rx for the sampling assembly 12 to collect the first detected voltage U_{LE}.

The second detection voltage-stabilization circuit 112B includes a second detection voltage-stabilization capacitor CY2, and the second unidirectional conduction circuit 112D includes a second diode D2. The second detection voltage-stabilization capacitor CY2, the second diode D2, the first resistor R1 and the sampling resistor Rx are sequentially connected in series to the second phase discharge path N and the low-voltage ground GND to form a detection loop, an anode of the second diode D2 is connected to the second detection voltage-stabilization capacitor CY2, and a cathode of the second diode D2 is connected to the first resistor R1. The sampling assembly 12 collects the second detected voltage U_{NE} of the second phase discharge path N through the sampling node Q.

The sampling assembly 12 includes a differential operational amplifier 122, a third capacitor CY3, a second resistor R2 and a third resistor R3. The third resistor R3 is connected between the reverse-phase end in2 of the differential operational amplifier 122 and the output end, out, of the differential operational amplifier 122. The second resistor R2 and the third capacitor CY3 are connected in series to a device ground E and a reverse-phase end in2 of the differential operational amplifier 122. The positive-phase end in1 of the differential operational amplifier 122 is connected to the sampling node Q, and the differential operational amplifier 122 respectively collect the first detected voltage U_{LE} and the second detected voltage U_{NE} by the sampling node Q.

When the voltage of the first phase discharge path L is greater than the voltage of the second phase discharge path N, the differential operational amplifier 122 detects the first detected voltage U_{LE} of the first phase discharge path L through the first detection circuit 111. When the voltage of the second phase discharge path N is greater than the voltage of the first phase discharge path L, the differential operational amplifier 122 detects the second detected voltage U_{NE} of the second phase discharge path N through the second detection circuit 112.

When the voltage of the first phase discharge path L is greater than the voltage of the second phase discharge path N, the positive-phase end in1 of the differential operational amplifier 122 is connected to the sampling node Q and is connected to the first phase discharge path L through the first detection circuit 111 to collect the first detected voltage U_{LE} from the sampling node Q, and the reverse-phase end in2 is connected to the device ground E by a third detection circuit. The third detection circuit includes a second resistor R2 and a third capacitor CY3. When the circuit operates, the positive output passes through the first detection voltage-stabilization capacitor CY1, the first diode D1, and the first resistor R1 to the positive-phase end in1 of the differential operational amplifier 122, the negative input passes through the device ground E and the second resistor R2 and the third capacitor CY3 to the reverse-phase end in2, and then the first detected voltage U_{LE} is outputted from the output end out of the differential operational amplifier 122.

When the voltage of the second phase discharge path N is greater than the voltage of the first phase discharge path L, the positive-phase end in1 of the differential operational amplifier 122 is connected to the sampling node Q and is connected to the second phase discharge path N through the second detection circuit 112, the second detected voltage U_{NE} is collected from the sampling node Q, and the reverse-phase end in2 is connected to the device ground E by the third detection circuit. When the circuit operates, the positive output passes through the second detection voltage-stabilization capacitor CY2, the second diode D2, and the first resistor R1 to the positive-phase end in1 of the differential operational amplifier 122, the negative input passes through the device ground E, the resistor R2 and the third capacitor CY3 to the reverse-phase end in2, and then the second detected voltage U_{NE} is output from the output end, out, of the differential operational amplifier 122.

The differential operational amplifier 122 transmits the collected first detected voltage U_{LE} and the second detected voltage U_{NE} to the signal processing circuit 13 through the output end, out.

The signal processing circuit 13 includes a clamping circuit 131 and a digital signal processor (DSP) 132. The clamping circuit 131 is connected between the output end, out, of the differential operational amplifier 122 and the digital signal processor 132, and is used to adjust the received voltage values of the first detected voltage U_{LE} and the second detected voltage U_{NE} in a preset range. The digital signal processor 132 is used to compare the first detected voltage U_{LE} and the second detected voltage U_{NE} in digital form. When the difference between the first detected voltage U_{LE} and the second detected voltage U_{NE} is greater than the preset threshold, it indicates that an electric-leakage fault occurs in the power supply 20.

It can be seen from the virtual short characteristic of an operational amplifier that the voltages of the positive-phase end in1 of the differential operational amplifier 122 and the reverse-phase end in2 of the differential operational amplifier 122 are equal. The resistances of the third resistor R3 and the sampling resistor Rx are equal to the resistance of the feedback resistor Rf of the differential operational amplifier, that is, Rx=R3=Rf, the resistance values of the first resistor R1 and the second resistor R2 are equal, both are R, that is, R1=R2=R, the first detection voltage-stabilization capacitor CY1, the second detection voltage-stabilization capacitor CY2 and the third capacitor CY3 are equal, that is, CY1=CY2=CY3, then the differential operational amplifier 122 outputs a common mode voltage: U_{LE}=(U_{L}-U_{E})*Rf/R.

When the voltage of the second phase discharge path N is greater than the voltage of the first phase discharge path L, the second detection circuit 112 is conducted and detects the second detected voltage U_{NE}, U_{NE}=(U_{R}-U_{E})*Rf/R.

When there is no insulation failure, that is, no electric-leakage, U_{LE}≈U_{NE}.

“GB/T18384-2020 Electric Vehicles Safety Requirements” sets requirements for electric-leakage of new energy electric vehicles: at the maximum operating voltage, the minimum value of the insulation resistance of the alternating current circuit should be greater than 50002/V, and an effective value of the maximum operating voltage is 220V. The national standard requires that the alternating current side insulation resistance should be ≥220V*500Ω/V=110 kΩ, therefore, when the equivalent insulation resistance to the vehicle body of the first phase discharge path L or the second phase discharge path N≤110Ω, an alarm indication must be provided, and simultaneously, the vehicle stops discharging.

When a electric-leakage fault occurs in the first phase discharge path L relative to the ground and/or the second phase discharge path N relative to the ground, if the insulation resistance RL of the first phase discharge path L relative to the device ground decreases, the first detected voltage U_{LE} decreases, so that a voltage U_{L} of the first phase discharge path L relative to the ground decreases. Simultaneously, a large voltage difference appears between the voltage U_{L} of the first phase discharge path L relative to the ground, and a voltage UN of the second phase discharge path N relative to the ground. When a deviation value of the common mode voltage is detected to reach a certain threshold M, that is, |U_{LE}-U_{NE}|>M, an electric-leakage fault is reported and the discharge is ended.

The deviation value threshold M of the common mode voltage is determined by connecting a 110Ω resistor in parallel to a path between the first phase discharge path L or the second phase discharge path N of the whole vehicle and the vehicle body of the driving device 100 and performing software matching. The threshold M can also be adjusted according to the needs of the driving device 100, and is not limited in this disclosure.

The device 10 for detecting electric leakage provided in this embodiment can make the insulation resistance between the alternating current ports of the power supply 20, that is, the first phase discharge path L and the second phase discharge path N, greater than or equal to about 20 MΩ while ensuring detection accuracy.

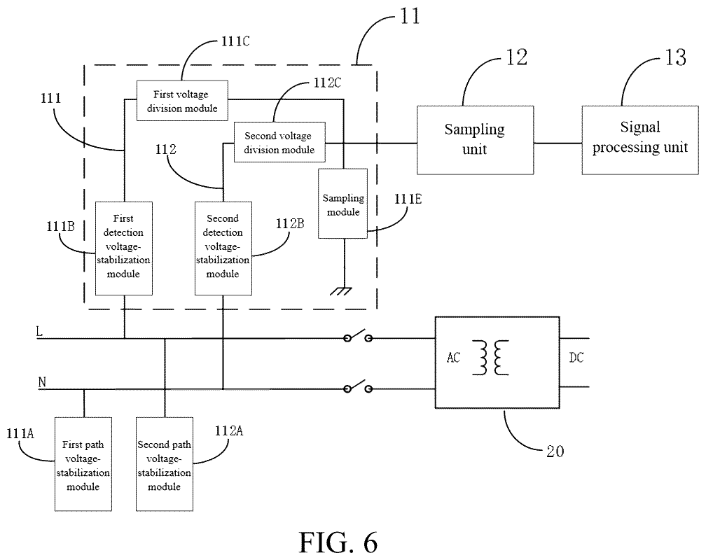

Referring to FIG. 6, which is a schematic connection diagram of functional modules of the device for detecting electric leakage in FIG. 2 disclosed in the fourth embodiment of the present disclosure. As shown in FIG. 6, the power supply 20 converts the received direct current DC into alternating current AC and outputs the electric energy to the electrical device outside the vehicle body through the first phase discharge path L and the second phase discharge path N.

The detection assembly 11 includes a first detection circuit 111 and a second detection circuit 112.

The first detection circuit 111 is connected between the first phase discharge path L and the device ground E and is connected to the second phase discharge path N by the device ground E to form a detection loop for detecting the common mode voltage between the first phase discharge path L and the device ground terminal E. The device ground E is connected to the earth by the vehicle body of the driving device 100.

The second detection circuit 112 is connected between the second phase discharge path N and the device ground E and is connected to the first phase discharge path L by the device ground E to form a detection loop for detecting the common mode voltage between the second phase discharge path N and the device ground E, that is, the second detected voltage U_{NE}.

The current output by the power supply 20 is an alternating current. When the first phase discharge path L discharges electricity, the first detection circuit 111 is conducted, and the sampling assembly 12 detects the first detected voltage U_{LE} from the first detection circuit. When the second phase discharge path N discharges electricity, the second detection circuit 112 is conducted, and the sampling assembly 12 detects the second detected voltage U_{NE} from the second detection circuit 112.

The first detection circuit 111 includes a first path voltage-stabilization circuit 111A, a first detection voltage-stabilization circuit 111B, a first voltage division circuit 111C and a sampling circuit 111E. The first detection voltage-stabilization circuit 111B, the first voltage division circuit 111C and the sampling circuit 111E are sequentially connected in series between the first phase discharge path L and the device ground E, while the first path voltage-stabilization circuit 111A is simultaneously connected between the second phase discharge path and the device ground E to form a detection loop.

When the first detection circuit 111 is conducted, the first detection voltage-stabilization circuit 111B is used to maintain the stability of the voltage received by the first detection circuit 111 from the first phase discharge path L. The first path voltage-stabilization circuit 111A is used to maintain the stability of the voltage transmitted to the second phase discharge path N by the first detection circuit 111. The first voltage division circuit 111C is used to divide the voltage in the first detection circuit 111 and simultaneously provide a unidirectional conduction function from the first phase discharge path L to the device ground E. The sampling circuit 111E is used to provide the sampling assembly 12 with the first detected voltage U_{LE}.

The second detection circuit 112 includes a second path voltage-stabilization circuit 112A, a second detection voltage-stabilization circuit 112B and a second voltage division circuit 112C. The second detection voltage-stabilization circuit 112B, the second voltage division circuit 112C and the sampling circuit 111E are sequentially connected in series between the second phase discharge path N and the device ground E. Simultaneously, the second path voltage-stabilization circuit 112A is connected between the first phase discharge path L and the equipment ground E to form a detection loop.

When the second detection circuit 112 is conducted, the second detection voltage-stabilization circuit 112B is used to maintain the stability of the voltage received by the second detection circuit 112 from the second phase discharge path N. The second path voltage-stabilization circuit 112A is used to maintain the stability of the voltage transmitted to the first phase discharge path by the second detection circuit 112. The second voltage division circuit 112C is used to divide the voltage in the second detection circuit 112 and simultaneously provide a unidirectional conduction function from the second phase discharge path N to the device ground E.

The sampling assembly 12 is electrically connected to the detection assembly 11, and is used to collect the first detected voltage U_{LE} of the first phase discharge path L and/or the second detected voltage U_{NE} of the second phase discharge path N from the detection loop,

The signal processing circuit 13 is connected to the sampling assembly 12 and is used to asynchronously receive the first detected voltage U_{LE} and the second detected voltage U_{NE} from the sampling assembly 12 and determine the electric-leakage characteristics of the power supply 20. When the voltage difference between the first detected voltage U_{LE} and the second detected voltage U_{LE} is greater than the threshold voltage, it indicates that an electric-leakage fault occurs in the power supply 20.

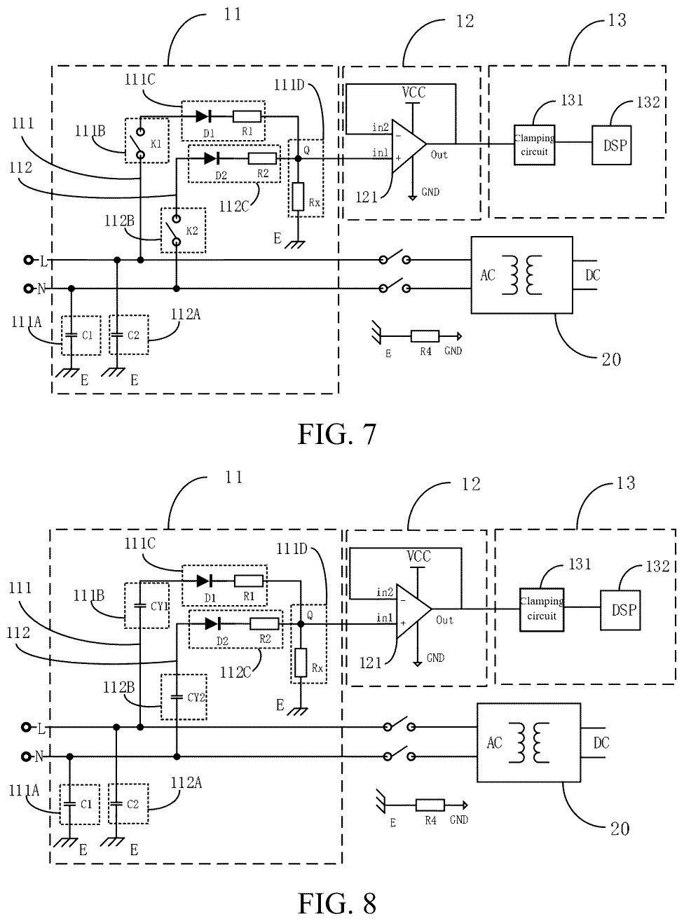

Please also refer to FIG. 7, which is an equivalent circuit diagram of the device for detecting electric leakage in FIG. 6. As shown in FIG. 7, in the first detection circuit 111, the first path voltage-stabilization circuit 111A includes a first path voltage-stabilization capacitor C1, the first detection voltage-stabilization circuit 111B includes a first switch K1, and the first voltage division circuit 111C includes The first diode D1 and the first resistor R1, the sampling circuit 111E includes a sampling node Q and a sampling resistor Rx. Among them, the first switch K1, the first diode D1, the first resistor R1 and the sampling resistor Rx are connected in series between the first phase discharge path L and the device ground E, and the anode of the first diode D1 is connected to the first phase discharge path L and the device ground E. A switch K1, the cathode of the first diode D1 is connected to the first resistor R1, the sampling node Q is located at the node between the first resistor R1 and the sampling resistor Rx, and the first path voltage-stabilization capacitor C1 is connected to the second phase discharge path Between N and the device ground E, the first detection circuit 111 forms a common mode voltage detection loop.

The first switch K1 is connected between the first phase discharge path L and the first diode D1, and is used to control the execution detection and stop detection of the first detection circuit 111. The sampling resistor Rx is connected between the first resistor R1 and the device ground E, and is used to provide a voltage sampling point for the sampling assembly 12. The sampling node Q is set between the first resistor R1 and the sampling resistor Rx. The sampling assembly 12 is connected to the sampling node Q and is used to collect the voltage of the sampling resistor Rx when the first detection circuit 111 detects the common mode voltage of the first phase discharge path L. The voltage value is also the first detected voltage U_{LE}.

In the second detection circuit 112, the second path voltage-stabilization circuit 112A includes a second path voltage-stabilization capacitor C2, the second detection voltage-stabilization circuit 112B includes a second switch K2, and the second voltage division circuit includes a second diode D2 and second resistor R2. The second switch K2, the second diode D2 and the second resistor R2 are sequentially connected in series between the second phase discharge path N and the sampling node Q. The anode of the second diode D2 is connected to the second switch K2, the cathode of the diode D2 is connected to the second resistor R2, and the second path voltage-stabilization capacitor C2 is connected between the first phase discharge path L and the device ground E, so that the detection loop is formed among the second phase discharge path N, the second switch K2, the second diode D2, the second resistor R2, the sampling resistor Rx, the equipment ground E, the second path voltage-stabilization capacitor C2 and the first phase discharge path L. The sampling assembly 12 obtains the second detected voltage U_{NE} by the voltage of the sampling node Q.

The sampling assembly 12 includes a voltage follower 121. A positive-phase end in1 of the voltage follower 121 is connected to the sampling node Q, a reverse-phase end in2 of the voltage follower 121 is connected to an output end, out, of the voltage follower 121, and the output end, out, is connected to the signal processing circuit 13 for collecting the first detected voltage U_{LE} and the second detected voltage U_{NE}, and the output end, out, transmits the first detected voltage U_{LE} and the second detected voltage U_{NE} to the signal processing circuit 13.

The signal processing circuit 13 includes a clamping circuit 131 and a digital signal processor (DSP) 132. The clamping circuit 131 is connected between the output end, out, of the voltage follower 121 and the digital signal processor 132, and is used to clamp the received voltage values of the first detected voltage U_{LE} and the second detected voltage U_{NE} to a preset voltage range. The digital signal processor 132 is used to receive the first detected voltage U_{LE} and the second detected voltage U_{NE} in digital form, and compare the first detected voltage U_{LE} and the second detected voltage U_{NE} in digital form. When the difference between the voltage U_{LE} and the second detected voltage U_{NE} is greater than the preset threshold, it indicates that an electric-leakage fault occurs in the power supply 20.

When the power supply 20 discharges through the first phase discharge path L and the second phase discharge path N, if no electric-leakage fault occurs, the common mode voltage between the first phase discharge path L and the device ground E is the same as the common mode voltage between the second phase discharge path N and the device ground E. Simultaneously, no current flows through the detection assembly 11 in the device 10 for detecting electric leakage, the sampling assembly 12 does not need to collect the first detected voltage U_{LE} or the second detected voltage U_{LE} from the sampling node, the signal processing circuit 13 does not need to perform determination of the electric-leakage characteristics of the power supply 20, and the device 10 for detecting electric leakage as a whole is in a low power consumption state.

When there is a voltage difference between the common mode voltage between the first phase discharge path L and the device ground E, and the common mode voltage between the second phase discharge path N and the device ground E, the detection assembly 11 detects the first detected voltage U_{LE} by the first detection circuit 111 and/or the second detected voltage U_{NE} by the second detection circuit 112. The sampling assembly 12 and the signal processing circuit 13 then perform the subsequent detection and determination in sequence.

In an embodiment, when the driving device 100 turns on the discharge function, that is, supplies power to the electrical device outside the vehicle body, the power supply 20 inverts the direct current into alternating current. The first switch K1 and the first diode D1 in the first detection circuit 111, the first resistor R1, the sampling resistor Rx and the first path voltage-stabilization capacitor C1 form the detection loop between the first phase discharge path L and the second phase discharge path N. The voltage follower 121 in the sampling assembly 12 collects the first detected voltage U_{LE} from the sampling node Q and transmits the first detected voltage U_{LE} to the clamping circuit 131. The clamping circuit 131 clamps the received first detected voltage U_{LE} and transmits it to the digital signal processor 132.

In an embodiment, in the second detection circuit 112, the second switch K2, the second diode D2, the second resistor R2, the sampling resistor Rx and the second path voltage-stabilization capacitor C2 from the detection loop between the second phase discharge path N and the first phase discharge path L. The voltage follower 121 in the sampling assembly 12 collects the second detected voltage U_{NE} from the sampling node Q and transmits the second detected voltage U_{NE} to the clamping circuit 131. The clamping circuit 131 clamps the received second detected voltage U_{NE} and transmits it to the digital signal processor 132.

Among them, the voltage follower 121 is connected to the low-voltage ground GND. A fourth resistor R4 is provided between the low-voltage ground GND and the device ground E. The potential between the low-voltage ground GND and the device ground E is the same, to avoid crosstalk between the low-voltage ground GND and device ground E.

The digital signal processor 132 compares the received first detected voltage U_{LE} and/or the second detected voltage U_{NE} in digital form. When the difference between the first detected voltage U_{LE} and the second detected voltage U_{NE} is greater than the preset threshold, it indicates that the power supply 20 has an electric-leakage fault. There is no need to identify the first detected voltage U_{LE} and the second detected voltage U_{NE}. When the digital signal processor 132 receives the first detected voltage U_{LE} or the second detected voltage U_{NE}, it only needs to detect the first detected voltage U_{LE} to obtain the second detected voltage U_{NE}, and then the difference between the first detected voltage U_{LE} and the second detected voltage U_{NE} can be calculated, or the first detected voltage U_{LE} can be obtained through the second detected voltage U_{NE}, and then the difference between the first detected voltage U_{LE} and the second detected voltage U_{NE} can be calculated.

When there is no electric-leakage fault in the discharge circuits of the power supply 20, the device 10 for detecting electric leakage is in a low power consumption state. For example, the power supply 20 outputs 220V AC power through the first phase discharge path L and the second phase discharge path N, which is used to power external electric device. When no electric-leakage fault occurs, the common mode voltage between the first phase discharge path L and the equipment ground E is 110V, the common mode voltage between the second phase discharge path N and the device ground E is 110V, there is no voltage difference between the first phase discharge path L and the second phase discharge path N, there is no current flowing between the first detection circuit 111 and the second detection circuit 112, and the device for detecting electric leakage is in a low power consumption state.

When the sampling assembly 12 collects the first detected voltage U_{LE} through the first detection circuit 111 or the second detected voltage U_{NE} through the second detection circuit 112, according to the alternating current characteristics, the signal processing circuit 13 can calculate the second detected voltage U_{NE} based on the first detected voltage U_{LE}, or the first detected voltage U_{LE} can be calculated based on the second detected voltage U_{NE}, and then the voltage difference between the first detected voltage U_{LE} and the second detected voltage U_{NE} can be calculated.

For example, when a electric-leakage fault occurs, when the common mode voltage between the first phase discharge path L and the device ground E is 160V, based on the voltage between the first phase discharge path L and the device ground E, the signal processing circuit 13 can calculate the common mode voltage between the second phase discharge path N and the device ground E, or when the common mode voltage between the second phase discharge path N and the device ground E collected by the sampling assembly 12 is 60V, there is a voltage difference between the first phase discharge path L and the second phase discharge path N.

The first detection circuit 111 and the second detection circuit 112 are conducted at different time points respectively, the first detected voltage U_{LE} and the second detected voltage U_{NE} can be detected and sampled by the first detection circuit 111. The digital signal processing circuit determines the difference between the first detected voltage U_{LE} and the second detected voltage U_{NE}, if the difference is greater than the threshold voltage, it indicates that an electric-leakage fault occurs when the power supply 20 supplies power.

The device 10 for detecting electric leakage provided in this embodiment can make the insulation resistance between the alternating current ports of the power supply 20, that is, the first phase discharge path L and the second phase discharge path N, greater than or equal to about 10 MΩ while ensuring detection accuracy.

Please refer to FIG. 8, which is an equivalent circuit diagram of the device for detecting electric leakage in FIG. 6 provided by the fifth embodiment of the present disclosure. As shown in FIG. 8, in the first detection circuit 111, the first path voltage-stabilization circuit 111A includes a first path voltage-stabilization capacitor C1, the first detection voltage-stabilization circuit 111B includes a first detection voltage-stabilization capacitor CY1, the first voltage division circuit 111C includes a first diode D1 and a first resistor R1, and the sampling circuit 111E includes a sampling node Q and a sampling resistor Rx. Among them, the first detection voltage-stabilization capacitor CY1, the first diode D1, the first resistor R1 and the sampling resistor Rx are connected in series between the first phase discharge path L and the device ground E. The anode of the first diode D1 is connected to the first detection voltage-stabilization capacitor CY1, the cathode of the first diode D1 is connected to the first resistor R1, the sampling node Q is located between the first resistor R1 and the sampling resistor Rx, and the first path voltage-stabilization capacitor C1 is connected between the second phase discharge path N and the device ground E, the first detection circuit 111 forms a common mode voltage detection loop.

The second detection stabilizing capacitor CY2 is connected between the first phase discharge path L and the first diode D1 to increase the impedance in the detection loop and maintain voltage stability of the first detection circuit 111. The sampling resistor Rx is connected between the first resistor R1 and the device ground E, and is used to provide a voltage sampling point for the sampling assembly 12. A sampling node Q is provided between the first resistor R1 and the sampling resistor Rx. The sampling assembly 12 is connected to the sampling node Q and is used to collect the voltage of the sampling resistor Rx, that is, the first detected voltage U_{LE} when the first detection circuit 111 detects the common mode voltage of the first phase discharge path L.

In the second detection circuit 112, the second path voltage-stabilization circuit 112A includes a second path voltage-stabilization capacitor C2, the second detection voltage-stabilization circuit 112B includes the second detection voltage-stabilization capacitor CY2, and the second voltage division circuit includes the second diode D2 and the second resistor R2. The second detection voltage-stabilization capacitor CY2, the second diode D2 and the second resistor R2 are connected sequentially in series between the second phase discharge path N and the sampling node Q, the anode of the second diode D2 is connected to the second detection voltage-stabilization capacitor CY2, the cathode of the second diode D2 is connected to the second resistor R2, and the sampling node Q is located between the first resistor R1 and the sampling resistor Rx. Simultaneously, the second path voltage-stabilization capacitor C2 is connected between the first phase discharge path L and the equipment ground E, so that the detection loop is formed among the second phase discharge path N, the second detection voltage-stabilization capacitor CY2, the second diode D2, the resistor R2, the sampling resistor Rx, the device ground E, the second path voltage-stabilization capacitor C2 and the first phase discharge path L. The sampling assembly 12 obtains the second detected voltage U_{NE} by collecting the voltage of the sampling node Q.

The capacitance value of the second path voltage-stabilization capacitor C2 and the second detection voltage-stabilization capacitor CY2 are equal, and the resistance value of the first resistor R1 is equal to the resistance value of the second resistor R2.

The sampling assembly 12 includes a voltage follower 121. The positive-phase end in1 of the voltage follower 121 is connected to the sampling node Q, the reverse-phase end in2 of the voltage follower 121 is connected to the output end, out, of the voltage follower 121, and the output end, out, is connected to the signal processing circuit 13 for collecting the first detected voltage U_{LE} and the second detected voltage U_{NE} from the sampling node Q, and the first detected voltage U_{LE} and the second detected voltage U_{NE} are transmitted to the signal processing circuit 13.

The signal processing circuit 13 includes a clamping circuit 131 and a digital signal processor (DSP) 132. The clamping circuit 131 is connected between the output end, out, of the voltage follower 121 and the digital signal processor 132, and is used to clamp the received voltage values of the first detected voltage U_{LE} and the second detected voltage U_{NE} in a preset range. The digital signal processor 132 is used to compare the first detected voltage U_{LE} and the second detected voltage U_{NE} in digital form. When a difference between the first detected voltage U_{LE} and the second detected voltage U_{NE} are greater than the preset threshold, it indicates that an electric-leakage fault occurs in the power supply 20.

In an embodiment, when the driving device 100 turns on the discharge function to supply power to electrical device outside the vehicle body, the power supply 20 inverts the direct current into alternating current, in the first detection circuit 111, the first detection voltage-stabilization capacitor CY1, the diode D1, the first resistor R1, the sampling resistor Rx and the first path voltage-stabilization capacitor C1 form a detection loop between the first phase discharge path L and the second phase discharge path N. The voltage follower 121 in the sampling assembly 12 collects the first detected voltage U_{LE} from the sampling node Q and transmits the first detected voltage U_{LE} to the clamping circuit 131. The clamping circuit 131 clamps the received first detected voltage U_{LE} and transmits it to the digital signal processor 132.

In the second detection circuit 112, the second detection voltage-stabilization capacitor CY2, the second diode D2, the second resistor R2, the sampling resistor Rx and the second path voltage-stabilization capacitor C2 form the detection loop between the second phase discharge path N and the first phase discharge path. The voltage follower 121 in the sampling assembly 12 collects the second detected voltage U_{NE} from the sampling node Q and transmits the second detected voltage U_{NE} to the clamping circuit 131. The clamping circuit 131 clamps the received second detected voltage U_{NE} and transmits it to the digital signal processor 132. The digital signal processor 132 compares the received first detected voltage U_{LE} and the second detected voltage U_{NE} in digital form. When the difference between the first detected voltage U_{LE} and the second detected voltage U_{NE} is greater than the preset threshold, it indicates an electric-leakage fault occurs in the power supply 20.

The frequency of the alternating current AC outputs by the power supply 20 is about f_{AC}=50 Hz, the impedance of the first voltage-stabilization capacitor C1 is R_{C1}=1/(2π*f_{AC}*C_{C1}), and the impedance of the first detection voltage-stabilization capacitor CY1 is R_{CY1}=1/(2π*f_{AC}*C_{CY1}), the impedance of the second path voltage-stabilization capacitor C2 is R_{C2}=1/(2π*f_{AC}*C_{C2}), and the impedance of the second detection voltage-stabilization capacitor CY2 R_{CY2}=1/(2π*f_{AC}*C_{CY2}).

$${U}_{L} = {R}_{X} / ( {R}_{C Y 1} + R 1 + {R}_{X} ) * {U}_{L E} , {U}_{N} = {R}_{X} / ( {R}_{C Y 2} + R 2 + {R}_{X} ) * {U}_{N E} .$$

When the driving device 100 starts to discharge and there is no insulation fault, U_{LE}≈U_{NE},

$$Rx / ( R 1 + Rx ) * \{ {R}_{C 2} // ( Rx + R 1 + {R}_{C Y 1} ) / [ {R}_{C 1} + {R}_{C 2} // ( Rx + R 1 + {R}_{C Y 1} ) ] * {U}_{L N} \} \approx Rx / \\ ( R 2 + Rx ) * \{ {R}_{C 1} // ( Rx + R 2 + {R}_{C Y 2} ) / [ {R}_{C 2} + {R}_{C 1} // ( Rx + R 2 + {R}_{C Y 2} ) ] * {U}_{L N} \} .$$

U_{LN} is the differential mode voltage between the first phase discharge path L and the second phase discharge path N.

“GB/T18384-2020 Electric Vehicles Safety Requirements” sets requirements for electric-leakage of new energy electric vehicles: at the maximum operating voltage, the minimum value of the insulation resistance of the alternating current circuit should be greater than 50002/V, and an effective value of the maximum operating voltage is 220V. The national standard requires that the alternating current side insulation resistance should be ≥220V*500Ω/V=110Ω, therefore, when the equivalent insulation resistance to the vehicle body of the first phase discharge path L or the second phase discharge path N≤110 kΩ, an alarm indication must be provided, and simultaneously, the vehicle stops discharging.

When an electric-leakage fault occurs at one end of the first phase discharge path L relative to the ground and/or the second phase discharge path N relative to the ground, if the insulation resistance RL of the first phase discharge path L relative to the device ground decreases, the first detected voltage U_{LE} decreases, so the voltage U_{L} at the L end of the first phase discharge path decreases. At this time, a large voltage difference will appear between the voltage U_{L} at the L end of the first phase discharge path and the voltage UN at the N end of the second phase discharge path. When it is detected that the deviation value of the common mode voltage reaches the voltage threshold M, that is, |U_{LE}-U_{NE}|>M, an electric-leakage fault is reported and the discharge ends. The common mode voltage difference threshold M needs to be matched based on the equivalent capacitance of the alternating current ports when the vehicle discharges, that is, the first path voltage-stabilization capacitor C1 and the second path voltage-stabilization capacitor C2 when the vehicle discharges. A 110 kΩ resistance is connected in parallel between the first phase discharge path L or the second phase discharge path N and the vehicle body of the driving device 100, and the common mode voltage difference threshold M is matched through software.

The device 10 for detecting electric leakage provided in this embodiment can make the insulation resistance between the alternating current ports of the power supply 20, that is, between the first phase discharge path L and the second phase discharge path N, greater than or equal to about 20 MΩ while ensuring detection accuracy.

By detecting the electric-leakage of the driving device through collecting the common mode voltage of the power supply discharge loop, it avoids setting the device for detecting electric leakage directly between the high-voltage circuit and the vehicle body of the driving device, improves the insulation performance of the whole vehicle, and meets the enterprise standard vehicle safety requirements. At the same time, when there is no electric-leakage fault in the power supply discharge loop, the device for detecting electric leakage is in a low power consumption state, which reduces the power consumption. The overall power consumption of the device for detecting electric leakage is low and the structure is simple, which greatly reduces the usage costs and production costs.

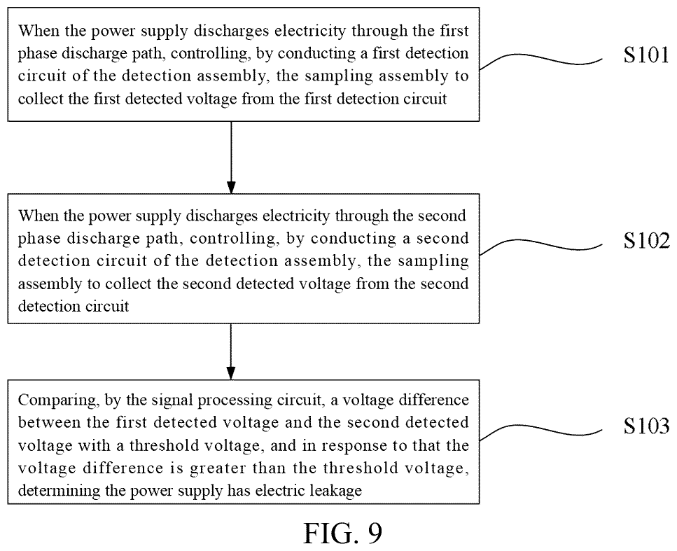

Referring to FIG. 9. FIG. 9 is a flow chart of a method for detecting electric leakage provided by the sixth embodiment of the present disclosure. As shown in FIG. 9, the method for detecting electric leakage can be applied to the aforementioned device for detecting electric leakage and driving device. The steps are:

In S101, when the power supply discharges electricity through the first phase discharge path, the first detection circuit is conducted, and the sampling assembly is controlled to collect the first detected voltage from the first detection circuit.

When the power supply 20 inverts direct current into alternating current to supply power to the electrical device outside the vehicle body, when the first phase discharge path L is conducted, the first detection circuit 111 is conducted, and the sampling assembly 12 can collect the first detected voltage U_{LE} from the sampling node in the first detection circuit 111, and the first detected voltage U_{LE} is the common mode voltage between the first phase discharge path L and the device ground E.

In S102, when the power source discharges electricity through the second phase discharge path, the second detection circuit is conducted, and the sampling assembly is controlled to collect the second detected voltage from the second detection circuit.

When the second phase discharge path N is conducted, the second detection circuit 112 is conducted, the sampling assembly 12 can collect the second detected voltage U_{NE} from the sampling node in the second detection circuit 112, and the second detected voltage U_{NE} is the common mode voltage between the second phase discharge path N and the device ground E.

In S103, compare the voltage difference between the first detected voltage and the second detected voltage with the threshold voltage. When the voltage difference is greater than the threshold voltage, it is determined that an electric-leakage fault occurs in the power supply.

The signal processing circuit 13 compares the received first detected voltage U_{LE} and the second detected voltage U_{NE} with an internally preset threshold voltage. If the voltage difference between the first detected voltage U_{LE} and the second detected voltage U_{NE} is greater than the threshold voltage, it indicates that an electric-leakage fault occurs in the first phase discharge path L or the second phase discharge path N.

It should be understood that the application of the present disclosure is not limited to the above examples. Those of ordinary skill in the art can make improvements or changes based on the above descriptions. All these improvements and changes should fall within the protection scope of the appended claims of the present disclosure.

What is claimed is:

1. A device for detecting electric leakage, comprising:
a detection assembly connected to a first phase discharge path and a second phase discharge path, the first phase discharge path and the second phase discharge path configured to connect to a power supply and transmit electricity outputted from the power supply when the power supply discharges electricity, and the detection assembly configured to establish a detection loop for the first phase discharge path and the second phase discharge path when the power supply discharges electricity,
a sampling assembly connected to the detection assembly, and configured to collect, from the detection loop, a first detected voltage of the first phase discharge path and a second detected voltage of the second phase discharge path, and
a signal processing circuit connected to the sampling assembly, and configured to receive the first detected voltage and the second detected voltage from the sampling assembly, and determine whether the power supply has electric leakage according to the first detected voltage and the second detected voltage.

2. The device according to claim 1, wherein
the detection assembly comprises a first detection circuit and a second detection circuit, and the first detection circuit is connected between the first phase discharge path and a low-voltage ground; and
the second detection circuit is connected between the second phase discharge path and the low-voltage ground; and
the sampling assembly is configured to collect the first detected voltage from the first detection circuit and collect the second detected voltage from the second detection circuit.

3. The device according to claim 2, wherein
the first detection circuit comprises a first detection voltage-stabilization circuit, a first unidirectional conduction circuit, and a sampling circuit connected in series between the first phase discharge path and the low-voltage ground; and
the second detection circuit comprises a second detection voltage-stabilization circuit and a second unidirectional conduction circuit, the second detection voltage-stabilization circuit, the second unidirectional conduction circuit, and the sampling circuit connected in series between the second phase discharge path and the low-voltage ground.

4. The device according to claim 3, wherein
the first detection voltage-stabilization circuit comprises a first switch, the first unidirectional conduction circuit comprises a first diode, and the sampling circuit comprises a first resistor, a sampling node, and a sampling resistor;
the first switch, the first diode, the first resistor, and the sampling resistor are connected in series between the first phase discharge path and the low-voltage ground, an anode of the first diode is connected to the first switch, a cathode of the first diode is connected to the first resistor, and the sampling node is connected between the first resistor and the sampling resistor;
the second detection voltage-stabilization circuit comprises a second switch, the second unidirectional conduction circuit comprises a second diode, and the second switch, the second diode, the first resistor, and the sampling resistor are connected in series between the second phase discharge path and the low-voltage ground; and an anode of the second diode is connected to the second switch, and a cathode of the second diode is connected to the first resistor; and
the sampling assembly collects the first detected voltage and the second detected voltage from the sampling node.

5. The device according to claim 3, wherein
the first detection voltage-stabilization circuit comprises a first detection voltage-stabilization capacitor, the first unidirectional conduction circuit comprises a first diode, and the sampling circuit comprises a first resistor, a sampling node, and a sampling resistor;
the first detection voltage-stabilization capacitor, the first diode, the first resistor, and the sampling resistor are connected in series between the first phase discharge path and the low-voltage ground, an anode of the first diode is connected to the first detection voltage-stabilization capacitor, a cathode of the first diode is connected to the first resistor, and the sampling node is connected between the first resistor and the sampling resistor;
the second detection voltage-stabilization circuit comprises a second detection voltage-stabilization capacitor, the second unidirectional conduction circuit comprises a second diode, the second detection voltage-stabilization capacitor, the second diode, the first resistor, and the sampling resistor are connected in series between the second phase discharge path and the low-voltage ground, an anode of the second diode is connected to the second detection voltage-stabilization capacitor, and a cathode of the second diode is connected to the first resistor; and
the sampling assembly collects the first detected voltage and the second detected voltage from the sampling node.

6. The device according to claim 4, wherein
the sampling assembly comprises a differential operational amplifier, a second resistor, a third resistor, and a third capacitor,
a positive-phase end of the differential operational amplifier is connected to the sampling node, and is configured to collect the first detected voltage and the second detected voltage from the sampling node, and
the second resistor and the third capacitor are connected in series between a reverse-phase end of the differential operational amplifier and a device ground, and the reverse-phase end of the differential operational amplifier is connected to an output end of the differential operational amplifier through the third resistor, and are configured to increase or decrease the first detected voltage and the second detected voltage according to a proportion and output the first detected voltage and the second detected voltage from the output end of the differential operational amplifier.

7. The device according to claim 1, wherein the detection assembly is further connected to a third phase discharge path, and the power supply outputs, respectively through the first phase discharge path, the second phase discharge path, and the third phase discharge path, currents with a same amplitude, a same frequency, and a same phase difference.

8. The device according to claim 1, wherein
the detection assembly comprises a first detection circuit and a second detection circuit,
the first detection circuit is connected between the first phase discharge path and a device ground, and is connected to the second phase discharge path by the device ground, and
the second detection circuit is connected between the second phase discharge path and the device ground, and is connected to the first phase discharge path through the device ground.

9. The device according to claim 8, wherein
the first detection circuit comprises a first detection voltage-stabilization circuit, a first path voltage-stabilization circuit, a first voltage division circuit, and a sampling circuit, the first detection voltage-stabilization circuit, the first voltage division circuit and the sampling circuit are connected in series between the first phase discharge path and the device ground, and the first path voltage-stabilization circuit is connected between the second phase discharge path and the device ground; and
the second detection circuit comprises a second detection voltage-stabilization circuit, a second path voltage-stabilization circuit, and a second voltage division circuit, the second detection voltage-stabilization circuit, the second voltage division circuit and the sampling circuit are connected in series between the second phase discharge path and the device ground, and the second path voltage-stabilization circuit is connected between the first phase discharge path and the device ground.

10. The device according to claim 9, wherein
the first detection voltage-stabilization circuit comprises a first switch, the first voltage division circuit comprises a first diode and a first resistor, the sampling circuit comprises a sampling resistor and a sampling node, and the first path voltage-stabilization circuit comprises a first path voltage-stabilization capacitor; and the first switch, the first diode, the first resistor, and the sampling resistor are connected in series between the first phase discharge path and the device ground, an anode of the first diode is connected to the first switch, a cathode of the first diode is connected to the first resistor, the sampling node is connected between the first resistor and the sampling resistor, and the first path voltage-stabilization capacitor is connected between the device ground and the second phase discharge path;
the second detection voltage-stabilization circuit comprises a second switch, the second voltage division circuit comprises a second diode and a second resistor, and the second path voltage-stabilization circuit comprises a second path voltage-stabilization capacitor; and the second switch, the second diode, the second resistor and the sampling resistor are connected in series between the second phase discharge path and the device ground, an anode of the second diode is connected to the second switch, a cathode of the second diode is connected to the second resistor, and the second path voltage-stabilization capacitor is connected between the device ground and the first phase discharge path; and
the sampling assembly is configured to collect the first detected voltage and the second detected voltage from the sampling node.

11. The device according to claim 9, wherein
the first detection voltage-stabilization circuit comprises a first detection voltage-stabilization capacitor, the first path voltage-stabilization circuit comprises a first path voltage-stabilization capacitor, the first voltage division circuit comprises a first diode and a first resistor, and the sampling circuit comprises a sampling node and a sampling resistor; and the first detection voltage-stabilization capacitor, the first diode, the first resistor, and the sampling resistor are connected in series between the first phase discharge path and the device ground, an anode of the first diode is connected to the first detection voltage-stabilization capacitor, a cathode of the first diode is connected to the first resistor, the sampling node is connected between the first resistor and the sampling resistor, and the first path voltage-stabilization capacitor is connected between the device ground and the second phase discharge path;
the second detection voltage-stabilization circuit comprises a second detection voltage-stabilization capacitor, the second voltage division circuit comprises a second diode and a second resistor, and the second path voltage-stabilization circuit comprises a second path voltage-stabilization capacitor; and the second detection voltage-stabilization capacitor, the second diode, the second resistor, and the sampling resistor are connected in series between the second phase discharge path and the device ground, an anode of the second diode is connected to the second detection voltage-stabilization capacitor, a cathode of the second diode is connected to the second resistor, and the second path voltage-stabilization capacitor is connected between the device ground and the first phase discharge path; and
the sampling assembly is configured to collect the first detected voltage and the second detected voltage from the sampling node.

12. The device according to claim 10, wherein
the sampling assembly comprises a voltage follower,
a positive-phase end of the voltage follower is connected to the sampling node, and is configured to collect the first detected voltage and the second detected voltage from the sampling node, and
a reverse-phase end of the voltage follower is connected to an output end of the voltage follower, and is configured to increase or decrease the collected first detected voltage and the second detected voltage according to a proportion and to output the collected first detected voltage and the second detected voltage from the output end of the voltage follower.

13. The device according to claim 1, wherein
the signal processing circuit comprises a clamping circuit and a digital signal processor, the clamping circuit is connected to the sampling assembly and the digital signal processor, and the clamping circuit is configured to clamp the first detected voltage and the second detected voltage received from the sampling assembly to a voltage range and to output the first detected voltage and the second detected voltage to the digital signal processor; and
the digital signal processor is configured to receive the first detected voltage and the second detected voltage, and to determine whether the power supply has electric leakage according to the first detected voltage and the second detected voltage.

14. A method for detecting electric leakage, applicable to a device for detecting electric leakage, wherein
the device comprises:
a detection assembly connected to a first phase discharge path and a second phase discharge path, the first phase discharge path and the second phase discharge path configured to connect to a power supply and transmit electricity outputted from the power supply when the power supply discharges electricity, and the detection assembly configured to establish a detection loop for the first phase discharge path and the second phase discharge path when the power supply discharges electricity,
a sampling assembly connected to the detection assembly, and
a signal processing circuit connected to the sampling assembly, and configured to receive a first detected voltage and a second detected voltage from the sampling assembly; and the method comprises:
when the power supply discharges electricity through the first phase discharge path, controlling, by conducting a first detection circuit of the detection assembly, the sampling assembly to collect the first detected voltage from the first detection circuit;
when the power supply discharges electricity through the second phase discharge path, controlling, by conducting a second detection circuit of the detection assembly, the sampling assembly to collect the second detected voltage from the second detection circuit; and
comparing, by the signal processing circuit, a voltage difference between the first detected voltage and the second detected voltage with a threshold voltage, and in response to that the voltage difference is greater than the threshold voltage, determining the power supply has electric leakage.

15. A vehicle, comprising a power supply and a device for detecting electric leakage,
the power supply configured to be connected to a first phase discharge path and a second phase discharge path, to discharge electricity through the first phase discharge path and the second phase discharge path, and to output an alternating current, and
the device comprising a detection assembly and a sampling assembly, and configured to detect electric leakage on the first phase discharge path and the second phase discharge path when the power supply discharges electricity.

16. The vehicle according to claim 15, wherein
the detection assembly comprises a first detection circuit and a second detection circuit, and the first detection circuit is connected between the first phase discharge path and a low-voltage ground; and
the second detection circuit is connected between the second phase discharge path and the low-voltage ground; and
the sampling assembly is configured to collect a first detected voltage from the first detection circuit and collect a second detected voltage from the second detection circuit.

17. The vehicle according to claim 16, wherein
the first detection circuit comprises a first detection voltage-stabilization circuit, a first unidirectional conduction circuit, and a sampling circuit connected in series between the first phase discharge path and the low-voltage ground; and
the second detection circuit comprises a second detection voltage-stabilization circuit and a second unidirectional conduction circuit, the second detection voltage-stabilization circuit, the second unidirectional conduction circuit, and the sampling circuit connected in series between the second phase discharge path and the low-voltage ground.

18. The vehicle according to claim 17, wherein
the first detection voltage-stabilization circuit comprises a first switch, the first unidirectional conduction circuit comprises a first diode, and the sampling circuit comprises a first resistor, a sampling node, and a sampling resistor;
the first switch, the first diode, the first resistor, and the sampling resistor are connected in series between the first phase discharge path and the low-voltage ground, an anode of the first diode is connected to the first switch, a cathode of the first diode is connected to the first resistor, and the sampling node is connected between the first resistor and the sampling resistor;
the second detection voltage-stabilization circuit comprises a second switch, the second unidirectional conduction circuit comprises a second diode, and the second switch, the second diode, the first resistor, and the sampling resistor are connected in series between the second phase discharge path and the low-voltage ground; and an anode of the second diode is connected to the second switch, and a cathode of the second diode is connected to the first resistor; and
the sampling assembly collects the first detected voltage and the second detected voltage from the sampling node.

19. The vehicle according to claim 17, wherein
the first detection voltage-stabilization circuit comprises a first detection voltage-stabilization capacitor, the first unidirectional conduction circuit comprises a first diode, and the sampling circuit comprises a first resistor, a sampling node, and a sampling resistor;
the first detection voltage-stabilization capacitor, the first diode, the first resistor, and the sampling resistor are connected in series between the first phase discharge path and the low-voltage ground, an anode of the first diode is connected to the first detection voltage-stabilization capacitor, a cathode of the first diode is connected to the first resistor, and the sampling node is connected between the first resistor and the sampling resistor;
the second detection voltage-stabilization circuit comprises a second detection voltage-stabilization capacitor, the second unidirectional conduction circuit comprises a second diode, the second detection voltage-stabilization capacitor, the second diode, the first resistor, and the sampling resistor are connected in series between the second phase discharge path and the low-voltage ground, an anode of the second diode is connected to the second detection voltage-stabilization capacitor, and a cathode of the second diode is connected to the first resistor; and
the sampling assembly collects the first detected voltage and the second detected voltage from the sampling node.

20. The vehicle according to claim 18, wherein
the sampling assembly comprises a differential operational amplifier, a second resistor, a third resistor, and a third capacitor,
a positive-phase end of the differential operational amplifier is connected to the sampling node, and is configured to collect the first detected voltage and the second detected voltage from the sampling node, and
the second resistor and the third capacitor are connected in series between a reverse-phase end of the differential operational amplifier and a device ground, and the reverse-phase end of the differential operational amplifier is connected to an output end of the differential operational amplifier through the third resistor, and are configured to increase or decrease the first detected voltage and the second detected voltage according to a proportion and output the first detected voltage and the second detected voltage from the output end of the differential operational amplifier.
